(19) United States
(12) Patent Application Publication
(10) Pub. No.: US 2009/0119911 A1
(43) Pub. Date: May 14, 2009

(54) FORMING A THREE-DIMENSIONAL STACKABLE DIE CONFIGURATION FOR AN ELECTRONIC CIRCUIT BOARD

(75) Inventor: Arvind K. Sinha, Rochester, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/177,685

(22) Filed: Jul. 22, 2008

Related U.S. Application Data
(63) Continuation of application No. 11/939,272, filed on Nov. 13, 2007, now Pat. No. 7,438,558.

(51) Int. Cl. H05K 3/30

(52) U.S. Cl. 29/832

(57) ABSTRACT

Forming a three-dimensional die configuration for an electronic circuit board includes locating a first electronic component in at least one cavity formed in a circuit board, and positioning a first substrate member in the at least one cavity. The first substrate member includes a first surface electrically connected to the first electronic component, and a second surface. A first surface of a double-sided land grid array is connected to the second surface of the first substrate member, and a first surface of a second substrate member is connected to a second surface of the double-sided land grid array. A second electronic component is mounted to a second surface of the second substrate member, and a portion of the second electronic component is covered with a thermal interface member. A cap member is mounted to the second electronic component and the thermal interface member to form a three-dimensional die configuration.

### CROSS-REFERENCE TO RELATED APPLICATIONS

The present application claims benefit to U.S. patent application Ser. No. 11/939,272, entitled “Three-Dimensional Stackable Die Configuration for an Electronic Circuit Board” filed Nov. 13, 2007 incorporated herein by reference in the entirety.

### BACKGROUND

This invention relates to electronic components and, more particularly, to forming a three-dimensional stackable die configuration for an electronic circuit board.

Electronic components are mounted to circuit boards or other substrates using a variety of connector schemes. Conventionally, a pin grid array (PGA) interface was used to mount a processor to a processor socket on a printed circuit board. A pin grid array includes a number of pins, typically on the processor, that mate with corresponding pin acceptors on the processor socket. More recently, ball grid array (BGA) and land grid array (LGA) interfaces are used to connect processors to circuit boards. Unlike the PGA interface, a chip mounted with a BGA or LGA interface does include pins. In place of pins, the chip is provided with gold or copper plated balls/pads that touch pins on the circuit board. The BGA and LGA interface provides a larger contact point that allows a processor to run at higher clock frequencies and also provides a more stable power connection. However, while BGA and LGA interfaces allow for higher clock speeds and provide more efficient power connections, the contact balls/pads require more surface area than, for example, pins. Open space on a printed circuit board is at a premium. As electrical devices shrink in size, free space for additional electronic components is rapidly decreasing.

### SUMMARY

Forming a three-dimensional die configuration for an electronic circuit board includes locating a first electronic component in at least one cavity formed in a circuit board, and positioning a first substrate member in the at least one cavity. The first substrate member includes a first surface electrically connected to the first electronic component, and a second surface. A first surface of a double-sided land grid array is connected to the second surface of the first substrate member, and a first surface of a second substrate member is connected to a second surface of the double-sided land grid array. A second electronic component is mounted to a second surface of the second substrate member, and a portion of the second electronic component is covered with a thermal interface member. A cap member is mounted to the second electronic component and the thermal interface member to form a three-dimensional die configuration. The three-dimensional die configuration provides a multiple electronic component mounting arrangement having a footprint of a single electronic component.

Additional features and advantages are realized through the techniques of exemplary embodiments of the present invention. Other embodiments and aspects of the invention are described in detail herein and are considered a part of the claimed invention. For a better understanding of the invention with advantages and features, refer to the description and to the drawings.

### BRIEF DESCRIPTION OF THE SEVERAL VIEWS OF THE DRAWINGS

The subject matter, which is regarded as the invention, is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates one example of a three-dimensional stackable die configuration for an electronic circuit board constructed in accordance with an exemplary embodiment of the present invention.

The detailed description explains the preferred embodiments of the invention, together with advantages and features, by way of example with reference to the drawing.

### DETAILED DESCRIPTION

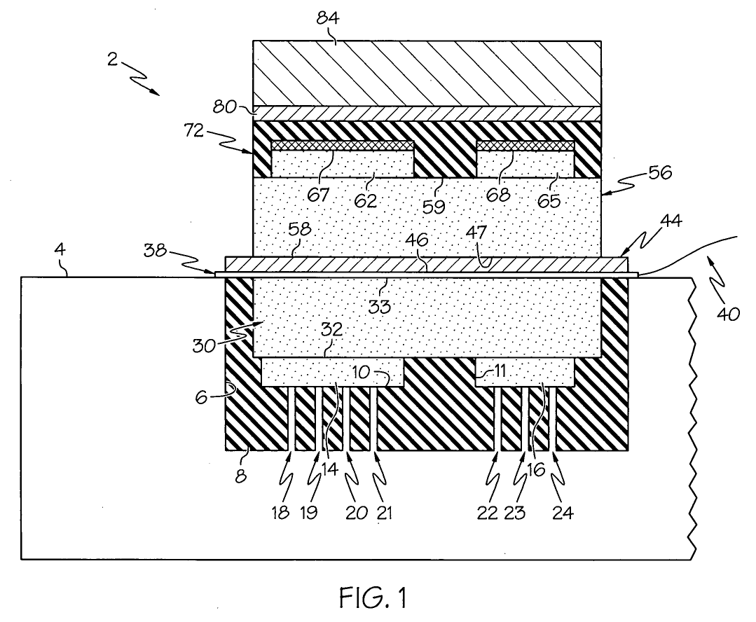

Turning now to the drawings in greater detail, it will be seen that in FIG. 1 there is shown a three-dimensional stackable die configuration 2 constructed in accordance with an exemplary embodiment of the present invention. Die configuration 2 includes the circuit board 4 having a cavity 6 filled with a thermal insulator or interface material 8. In accordance with the embodiment shown, thermal interface material 8 forms first and second board dies 10 and 11 within which are arranged first and second electronic components or chips 14 and 16 respectively. In further accordance with the exemplary embodiment shown, first and second electronic components 14 and 16 are low power electronic chips having a power output of about 50 watts or more. Heat generated by operation of first and second electronic components 14 and 16 is readily dissipated through thermal interface material 8 as well as a plurality of vias 18-24 formed in circuit board 4. That is, vias 18-24 establish a heat dissipation path for first and second electronic components 14 and 16.

First and second electronic components 14 and 16 are electrically connected to a first substrate member 30 having a first surface 32 and an opposing, second surface 33. First substrate member 30 is formed from an organic material such as, for example, a ceramic or polyamide layer and provides an electrical interface with a flex cable 38. Flex cable 38 includes a cable and having a plurality of conductors, that provide input and output I/O interface for first and second electronic components 14 and 16 as well as an additional electronic components as will described more fully below. In any event, flex cable 38 is electrically coupled to a double-sided land grid array 44 having a first surface 46 and an opposing, second surface 47. Land grid array 44 serves as an interface to a second substrate member 56 having first and second surfaces 58 and 59. In a manner similar to that described above, second substrate member 56 is formed from an organic material such as ceramic or a polyamide layer. Double-sided land grid array 44 enables multiple electronic components to be stacked on circuit board 4. The particular details of double-sided land grid array 44 and the connection to flex cable 38 can be found in commonly assigned U.S. Patent Application entitled “Stacked Multiple Electronic Component Interconnect Structure”, Ser. No. 11/938,858 filed Nov. 13, 2007, the contents of which are incorporated herein by reference in their entirety.

As further shown in FIG. 1, three dimensional die configuration 2 includes a third electronic component 62 and a fourth electronic component 65 that are electrically connected to second surface 59 of second substrate member 56. Third and fourth electronic components 62 and 65 are high power electronic components or chips having an output of about 200 watts or more. In any event, in order to provide adequate heat dissipation for three-dimensional die configuration 2, electronic components 62 and 65 are covered by a corresponding thermal interface layer 67 and 68. Each thermal interface layer 67 and 68 provides a thermal dissipation path that allows heat generated by third and fourth electronic components 62 and 65 to pass, via conduction, to a cover member 72. Cover member 72 is also configured to secure third and fourth electronic components 62 and 65 to circuit board 4.

In accordance with the exemplary embodiment shown, cover member 72 is formed from a heat conducting material, such as steel or copper. The heat conducting material, combined with an additional thermal interface layer 80, and a heat sink 84, provide additional heat dissipation. In this manner, heat generated by the operation of third and fourth electronic components 62 and 65 is conducted away from three-dimensional die configuration 2 allowing multiple electronic components to be placed in a footprint, or on an area of circuit board 2, previously occupied by only a single electronic component. With this configuration, the overall number of electronic components mounted to circuit board 4 can be increased while simultaneously, shrinking the overall size of the circuit board in order to accommodate smaller more compact electronic devices. It should be appreciated at this point that while the first and second electronic components are shown mounted within a cavity formed in the circuit board and surrounded by a thermal interface material, the electronic components can alternatively be mounted to an opposing side of the circuit board with the first substrate member providing an interface to an additional three dimensional stackable die configuration.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A method of forming a three-dimensional die configuration for an electronic circuit board, the method comprising:
locating a first electronic component in at least one cavity formed in a circuit board;
positioning a first substrate member in the at least one cavity, the first substrate member including a first surface electrically connected to the first electronic component, and a second surface;
connecting a first surface of a double-sided land grid array to the second surface of the first substrate member;
connecting a first surface of a second substrate member to a second surface of the double-sided land grid array;
mounting a second electronic component to a second surface of the second substrate member;
covering a portion of the second electronic component with a thermal interface member; and
mounting a cap member to the second electronic component and the thermal interface member to form a three-dimensional die configuration, the three-dimensional die configuration providing a multiple electronic component mounting arrangement having a footprint of a single electronic component.

2. The method of claim 1, wherein locating the first electronic component in at least one cavity comprises locating a low power electronic chip having an output of about 50 watts in the at least one cavity, and mounting the second electronic component to the second surface of the second substrate member comprises mounting a high power electronic chip having an output of about 200 watts to the second surface of the second substrate member.

3. The method of claim 2, further comprising:
covering at least a portion of the cap member with another thermal interface member; and
mounting a heat sink to the another thermal interface member, the heat sink providing heat dissipation for the high power electronic chip.

4. The method of claim 1, further comprising:
positioning a flex cable between the double sided land grid array and one of the first and second substrate members, the flex cable including a plurality of conductors that provide an input and output (I/O) interface between at least one of the first and second electronic components and the circuit board.

5. The method of claim 1, further comprising:
forming a plurality of vias in the circuit board at the at least one cavity, the plurality of vias providing a heat dissipation path for the first electronic component.
